(19) United States
(12) Patent Application Publication
(10) Pub. No.: US 2025/0284637 A1
(43) Pub. Date: Sep. 11, 2025

(54) EMULATED-ARCHITECTURE MEMORY

(71) Applicant: Rambus Inc., San Jose, CA (US)

(72) Inventors: Wendy Elsasser, Austin, TX (US); Taeksang Song, San Jose, CA (US)

(21) Appl. No.: 19/018,255

(22) Filed: Jan. 13, 2025

Related U.S. Application Data
(60) Provisional application No. 63/562,655, filed on Mar. 7, 2024.

(51) Int. Cl. G06F 12/06

(52) U.S. Cl. CPC G06F 12/06

(57) ABSTRACT

Stacked-die memory components are programmably configurable to emulate memory architectures having fewer logical/virtual memory banks, bank groups and/or integrated circuit dies than the resident physical quantities of those resources, substantially reducing command scheduling complexity in counterpart host component and thereby enabling deeper scheduling queue implementation and correspondingly higher bus utilization efficiency.

### CROSS REFERENCE TO RELATED APPLICATIONS

This application hereby claims priority to and incorporates by reference U.S. Provisional Application No. 63/562,655 filed Mar. 7, 2024.

### TECHNICAL FIELD

The disclosure herein relates to integrated-circuit memory components and memory systems.

### DRAWINGS

The various embodiments disclosed herein are illustrated by way of example, and not by way of limitation, in the figures of the accompanying drawings and in which like reference numerals refer to similar elements and in which:

FIG. 1 illustrates an embodiment of a memory system having a host control component coupled to an emulated-architecture (EA) memory module;

FIG. 2 illustrates exemplary emulated memory architectures that may be programmed within memory components having the physical stacked-DRAM-die architecture shown in FIG. 1 as well as extensions of that same physical memory component architecture to eight DRAM dies and sixteen DRAM dies;

FIG. 3 illustrates exemplary configuration operations within the emulated-architecture memory component of FIG. 1;

FIG. 4 illustrates an exemplary set of emulation-mode configurations within a stack of sixteen dies, each having 32 storage banks (512 storage banks altogether) arranged in groups of four within respective bank groups;

FIG. 5 illustrates an exemplary rank-to-rank deskew circuitry implemented within the FIG. 1 memory component to levelize transactional timing across all physical intra-package ranks despite flight-time differences with respect to outgoing commands and incoming read data;

FIG. 6 illustrates an exemplary implementation of the FIG. 5 rank-to-rank deskew circuitry that levelizes memory read latency by delaying command launch time for lower-latency DRAM dies to match the memory read latency of the most remote (highest-latency) DRAM die; and

FIG. 7 illustrates an exemplary emulated-architecture memory component through having parallel internal data paths to eliminate bus turnover delay (i.e., latency penalty otherwise incurred when switching data bus driver from one memory die to another and/or from dedicated logic die to memory die).

### DETAILED DESCRIPTION

Stacked-die memory components programmably configurable to emulate memory architectures having fewer logical/virtual memory banks, bank groups and/or integrated circuit dies than the resident physical quantities of those resources are disclosed in various embodiments herein together with memory control components capable of configuring such reduced-complexity emulated architectures within those stacked-die memory components. By programming stacked-die memory components (and thus memory modules populated by those memory components) to emulate reduced resource count/reduced complexity architectures, control components may operate with deeper command-scheduling queues, and thereby achieve correspondingly higher bandwidth utilization, than conventional control components that are constrained to shallower command-scheduling queues in order to track and manage individual timing limits for all physical resources within those same memory components.

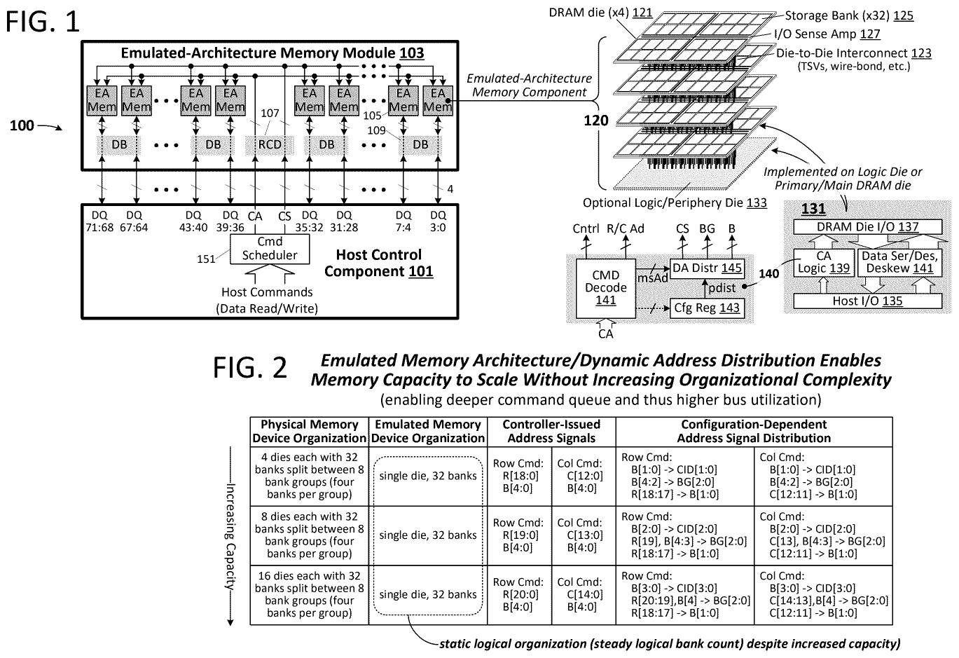

FIG. 1 illustrates an embodiment of a memory system 100 having a host control component 101 coupled to an emulated-architecture (EA) memory module 103—that is, a memory module (a dual inline memory module (DIMM) in this instance, though any other practicable module form factor may also/alternatively be deployed within system 100) populated by stacked-die memory components 105 having programmable/configurable storage resource architectures (“emulated-architecture” memory components 105). Host controller 101 (e.g., dedicated memory controller, central processing unit (CPU) or any other component having a memory control function,) outputs command/address values (commands and addresses) to memory module 103 over a command/address path (“CA”) and receives read data from or outputs write data to the memory module over an exemplary 72-bit data path, composed in the depicted embodiment by 18 4-bit (nibble-sized) sets of data links (“DQ”). Control component 101 additionally outputs chip-select signals, “CS”, to select one of multiple physical memory ranks in connection with a commanded memory/access operation, each such physical memory rank constituted by a respective set (rank) of memory components 105—e.g., one such rank being disposed on each face of memory module 103—having a collective data interface width that matches the host data interface width and controller-to-module data path width (e.g., eighteen memory components 105 each having a 4-bit wide data interface to collectively match the 72-bit data path width). By this arrangement, constituent memory components 105 within the selected physical rank (i.e., selected in response to chip-select signal assertion by host control component 101) concurrently sample or transmit respective 4-bit slices of data conveyed via the 72-bit DQ path (i.e., data slices associated with/corresponding to a command conveyed on the command/address path), executing such data sampling or transmission iteratively over a temporal burst interval. In one embodiment, for example, each memory component 105 samples or transmits 4-bit slices of the transferred data volume in response to each of eight successive edges of a timing signal and thus receives or outputs four bytes of data per memory read or write command—a respective 4-byte component of a 72-byte data volume that includes a 64-byte cache line and 8-byte error correction code (ECC). Though not specifically shown, host controller 101 may also output various timing signals (clock signals and/or strobe signals) to time reception of command/address signals and data signals within memory module 103 (two or more of which may be coupled in parallel to the DQ and CA paths) and more specifically within one or more selected physical and logical memory ranks disposed on module 103. In one embodiment, for example, host controller 101 forwards a differential clock signal to memory module 103 to time reception of command/address signals therein (and establish a primary internal clock domain within various memory components 105) and also outputs or receives data strobe signals over differential data strobe links (DQS) associated with respective subsets of data path links (DQ). Host controller 101 may also output additional control signals to control on-die termination (ODT), enable or disable clock reception and so forth within one or more logical memory ranks.

Within emulated-architecture (EA) memory module 103, command/address, chip-select and other control signals may be delivered to (EA) memory components 105 via an optional RCD (registered clock driver) component 107, and data signals may likewise be delivered to individual memory components 105 via a data buffer component 109. In one embodiment, for example, the RCD forwards command/address signals to the command/address inputs of all EA memory components 105 resident on module 103 while enabling (in accordance with one or more incoming chip-select signals) only one physical rank of those components to sample and respond the coming command/address signals. Similarly, each data buffer component 109 may selectively transfer signals between an 8-bit slice of the 72-bit DQ path and two pairs of ×4 (4-bit data width) EA memory components within respective/different physical memory ranks, thus reducing the electrical loading of the high-speed DQ links extending between control component and memory module 103 (i.e., as otherwise, multiple EA memory components—one from each physical rank—would be coupled in parallel to each 4-bit slice of the 72-bit DQ path).

In an embodiment shown in detail view 120 (FIG. 1), each EA memory component 105 is implemented by a stack of dynamic random access memory (DRAM) dies 121 (though any bank-based semiconductor memory die may alternatively or additionally be included in the die-stack in other embodiments) interconnected by through-silicon vias (TSVs), wire bonds and/or any other practicable intra-package die-to-die interconnect (123). As shown, each DRAM chip 121 in the 4-die stack (more or fewer DRAM dies may be present) includes 32 storage banks 125 (e.g., each implemented by one or more arrays or mats of DRAM cells) coupled to input/output sense amplifiers (IO sense amps) 127, the latter coupled in turn to die-to-die interconnects 123. Component control circuitry 131, implemented either on a primary one of the DRAM dies 121 (e.g., the bottom die in the stack) or a dedicated “logic” or “periphery” die 133, includes a host interface 135 coupled to receive command/address signals (and other control signals) and exchange data signals (transmitting or receiving) directly or indirectly from/with the host memory control component, and a DRAM die interface 137 to convey command/address signals to (and other control signals) and exchange data signals with the other DRAM dies (or all DRAM dies 121 in an implementation having a dedicated logic die 133). Command/address signals received via host I/O circuitry 135 are supplied to a command/address logic circuit 139 having (e.g., as shown in detail view 140), a command decoder 141, configuration register 143 and dynamic address distribution circuitry 145. The command decoder generates (“decodes”), in accordance with one or more command bits embedded within the host-supplied command/address value, various DRAM die control signals, “Cntrl” (e.g., data-load, data-output, row-address strobe, column-address strobe, precharge enable, etc.), forwarding those control signals to the DRAM dies via I/O circuitry 137 together with row/column address signals (“R/C Ad”) embedded within the same command/address value. Upon receiving a register programming command which, as discussed below, may be issued by the host control component (or other components/systems, for example, during system production) to configure one of multiple emulated-architecture modes within memory component 105, the command decoder enables storage of emulation-control settings within configuration register 143, (i.e., programming the configuration register with one or more settings received within or in association with the register programming command issued by the host), with such programmed emulation-control setting being output to dynamic address distribution circuitry 145 in the form of programmed address distribution value, “pdist.” The command decoder additionally supplies a number of the most-significant address bits (msAd) embedded in the host-supplied command/address value to dynamic address distribution circuitry 145 which, in turn, selectively forwards/outputs those address bits to the DRAM dies (i.e., via interface 137 and in accordance with the programmed address distribution value) in the form of intra-package chip-select signals (CS), bank-group address signals (BG) and bank address signals (B). Thus, when an EA memory component 105 is selected to respond to an incoming host command (i.e., selected by assertion of a physical-rank chip-select signal), host I/O 135 samples the incoming command/address value, command decoder 141 (receiving the command/address from the host I/O) outputs command-responsive control signals to the DRAM dies via I/O circuitry 137, and the command decoder and dynamic address distribution circuitry (the latter receiving most-significant bits of the address bits embedded in the CA value) collectively output intra-package chip-select, bank-group, bank and row/column address values to the DRAM dies via I/O circuitry 137. In the case of a memory write command, corresponding write data (transmitted by the host control component) is received via the host I/O and conveyed to the DRAM die I/O via data serializer/deserializer 141 (a circuit block that optionally includes timing deskew circuitry as discussed below), for example, deserializing data received via 16 successive 4-bit transfers over the 4-bit physical interface of the EA memory component into a 64-bit value (having 16 4-bit components) that is then driven to the target DRAM die in response to a lower-speed clock (e.g., both rising and falling edges of a 6.4 GHz data strobe used to sample 16 4-bit values that are deserialized into a single 64-bit value that is transmitted to DRAM dies synchronously with respect to a rising (or falling) edge of a 400 MHz internal clock). Conversely, data retrieved from a selected physical memory bank in response to a host read command (i.e., command received from the host control component via host I/O 135) is transmitted to the DRAM die interface (137) of component control circuitry 131 in response to a timing edge of the lower-frequency internal clock and then serialized for high-speed burst transmission (i.e., sequence of sixteen successive 4-bit transmissions executed synchronously with respect to rising and falling edges of a 6.4 GHz timing signal) to the host control component via I/O circuitry 135.

Operational timing within the EA memory component 105 is constrained by data propagation time delays (e.g., between various circuit blocks traversed by data flowing between the host I/O and addressed storage bank) and time-division allocation of shared resources (e.g., intra-bank bit lines, per-bank sense amplifiers, I/O sense amplifiers 127, die-to-die interconnects 123, etc.). In a number of embodiments, command scheduling circuitry 151 within host control component 101 enforces these timing constraints by tracking the operational state of each memory rank and each memory bank, activating constraint timers within an operational state machine for the subject rank and/or bank at command issuance (e.g., start a countdown timer for rank/bank for which activation command is issued) and responding to feedback signals from those timers as they expire—an arrangement supported by a many-to-many signaling arrangement between a scheduling queue and timer/state circuitry within the rank and bank state machines (e.g., each entry in the scheduling queue having multiple respective outputs to the timers and operational status circuitry for each rank and bank and, conversely, multiple respective inputs from the timers within that operational status circuitry). Consequently, the number of state-management signals transferred between the scheduling queue and rank/bank state machines (e.g., start-time outputs, timer-expired inputs) proliferates rapidly as the number of physical storage banks within a subject memory component grows (e.g., as die stacks become taller, as bank counts per die increase, etc.). As the control signals feeding back to the scheduler (e.g., to green-light/enable issuance of queued commands requiring previously occupied resources) are supplied to each command-in-waiting within the command queue, the deeper the queue (i.e., the higher the number of commands from which the scheduler may select as the next issued command), the higher the number of state-management control signals. Because the host command scheduler generally operates by selectively reordering queued commands so as to avoid contention/timing-bottlenecks at shared resources, deepening the command queue substantially increases data bus utilization efficiency (i.e., as the scheduler has a larger pool of commands to choose from and thus more opportunity to avoid shared-resource contention) but at the same time increases the number of intra-scheduler control signals needed to manage timing. Because timing closure must be met in any scheduler design (i.e., meeting the timing budget—typically set by a clock cycle time—required for input signal setup time, output signal generation and output signal hold time), designers are increasingly forced to reduce command queue depth—sacrificing critical bus utilization efficiency—to meet the ever-tightening timing closure window imposed by the proliferating numbers of memory banks and intra-package memory ranks within stacked-die DRAM components. In the FIG. 1 embodiment, timing closure constraints within the host command scheduler are dramatically reduced by programming EA memory components 105 (and thus memory module 103) to emulate memory component (and thus memory module) architectures with substantially reduced complexity—fewer intra-package memory ranks (i.e., fewer DRAM dies) and/or fewer logical banks per rank so that the operational timing state machines required by the host controller are correspondingly simplified, reducing control-signal exchange between the command queue and rank/bank state machines to a mere fraction of that required to manage operations with respect to all physical storage banks within EA memory module 103 and thus enabling timing closure to be met with respect to substantially deeper scheduling queues than otherwise possible, significantly increasing bus utilization efficiency.

FIG. 2 illustrates exemplary emulated memory architectures that may be programmed within memory components 105 having the physical stacked-DRAM-die architecture shown at 120 in FIG. 1 as well as extensions of that same physical memory component architecture to eight DRAM dies and sixteen DRAM dies. When emulation mode is programmed/enabled within the four-die (×4) memory component, the four individually selectable DRAM dies—that is, four intra-package ranks each having eight bank groups with four banks per group and thus 32 banks per die and 128 banks per full memory component—emulate (i.e., are perceived and operated by the host control component) as a single die/single rank having 32 banks and thus a memory component architecture having a memory rank count and memory bank count reduced by a factor of four. The number of rank and bank state machines within the host command-scheduling circuitry may thus likewise be reduced by a factor of four, substantially reducing the number of state control/management signals extending to/from the command queue and thus enabling deeper command queue implementation and correspondingly higher bandwidth utilization than in embodiments that manage state/timing constraints for the full physical panoply of memory rank and bank resources. In one embodiment, each bank group within the emulated architecture is constituted by a single emulated memory bank (i.e., one emulated memory bank corresponds to four physical banks) so that, from the host controller perspective, each memory bank within the emulated memory component architecture is four times as deep (four times as many addressable rows of storage cells) for purposes of row-addressing and/or four times as wide (four times as many addressable columns of storage cells for purposes of column addressing). Accordingly, row and column addresses issued by the host controller are extended by two bits beyond that needed to resolve a physical storage row or physical storage column, with those additional bits being routed by dynamic address distribution circuitry (e.g., as shown at 145 in FIG. 1) to select one of four physical banks within a given bank group. More specifically, as shown in the configuration-dependent address signal distribution shown in FIG. 2, the five bank address bits supplied by the host in association with a given row or column command are applied (dynamically routed via distribution circuitry 145 in accordance with the programmed emulation mode) to select one of the four physical dies (routing the least two significant bits of the bank address, for example, to the chip ID (CID) input of a chip-selection circuit—B[1:0]->CID[1:0]—and thus selecting one of four physical memory dies (one of four intra-package ranks) as the intended recipient of the row or column command) and to select one of eight bank groups on the selected physical die (e.g., selecting one of eight physical bank groups according to the most significant three bits of the bank address—B[4:2]->BG[2:0]). The two most significant row address bits (or most significant column address bits in the case of a column command) are routed, by the dynamic address circuitry, onto the bank address path and thus select one of four physical banks within the bank group (and on the die) selected by the bank address bits (i.e., R[18,17]->B[1:0]; C[12:11]->B[1:0]). The remaining row address bits (R[16:0]) or column address bits (C[10:0]) are applied to select a physical row or column (as the case may be) as they would be in any operating mode (emulated or non-emulated) and thus are not specifically shown in FIG. 2. Of course, the number of row or column address bits may vary in accordance with the physical storage bank size (more or fewer row address bits for physically deeper or shallower storage banks, more or fewer column address bits for physically wider or narrower storage banks).

Continuing with the FIG. 2 examples, emulation of an 8-die stack or 16-die stack (256 banks or 512 banks total, respectively, where each physical die is implemented as shown at 120 in FIG. 1) as a single 32-bank die yields a one-bit deeper row address/column address or two-bit deeper row address/column address (respectively), with the dynamic address distribution circuitry (i.e., circuit block shown at 145 in FIG. 1) routing incoming bank and row (or column) address bits onto the chip-ID, bank group and bank paths shown in the final two rows of the FIG. 2 table. Accordingly, despite increasing memory capacity as the die stack grows (and likewise as the physical resource count per die grows), the logical organization perceived by the host controller (i.e., the emulated architecture) remains static, enabling, among other benefits, substantially deeper (e.g., 50% deeper, 100% deeper or more) command scheduling queue implementation within the host control component and thus higher bus utilization efficiency than otherwise possible under the same timing closure constraints. Emulated memory architectures may also enable re-use of legacy controller designs without unnecessary overprovisioning in the lower capacity configurations (while support for larger numbers of emulated rows and/or columns is required, the overhead to provision additional row/column address bits to cover multiple solution spaces should be less costly than controller re-design and/or overprovisioning) and also provide configurable balance between parallel resources and controller complexity, for example, balancing parallelism and complexity according to use case.

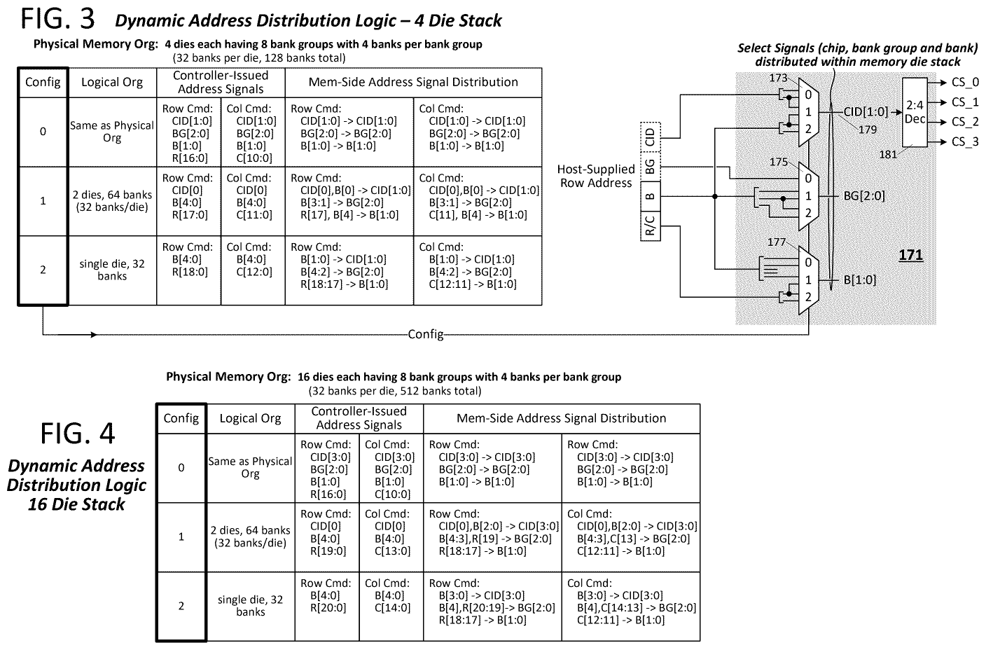

FIG. 3 illustrates exemplary configuration operations within the emulated-architecture memory component of FIG. 1. In the first listed configuration (Config=0), emulation is effectively disabled so that the logical and physical organization of the memory component are one and the same. In that case, the control component issues row and column commands bearing the address fields as required by the underlying physical architecture of the EA memory component—in this example, two chip-ID bits (CID[1:0]) to select one of four intra-package ranks (or dies), three bank-group bits (BG[2:0]) to select one of eight bank groups on the selected die, two bank bits (B[1:0]) to select one of the four banks within the selected bank group, and row/column address values according to the physical bank storage row and column count (R[16:0] and C[10:0] in this example). Referring to the conceptual view of dynamic address distribution circuitry at 171 (e.g., an exemplary instantiation of circuit 145 shown in FIG. 1), the configuration setting (“Config”) is applied to control inputs address-field multiplexers 173, 175 and 177 to select the configuration-0 option in each such that the CID bits are routed via multiplexer 173 onto CID path 179 (and from that point decoded within 2:4 decoder 181 to assert one of four intra-package chip-select signals, CS_0, CS_1, CS_2 or CS_3, and thereby enable command execution within the address-specified one of the four DRAM dies), bank-group bits are routed via multiplexer 175 onto the bank-group address path, and bank address bits are routed via multiplexer 177 onto the bank-address path—a one-to-one routing between incoming signals and their respective resource-address paths.

Still referring to FIG. 3, when a two-die emulation setting—configuration ‘1’—is specified (i.e., programmed), the EA memory component emulates a two-rank component having 32 storage banks per rank and thus a 64-bank memory architecture. In that emulation mode, the host control component perceives a memory architecture having half as many storage banks, each with double-capacity (2× capacity), as the underlying physical architecture and thus issues command/address values bearing a single CID bit (CID[0]), a five-bit bank address (B[4:0]) and row (or column) address fields that are extended by one bit beyond the physical sizes of the physical DRAM storage bank. As shown by the memory-side address signal distribution columns of the FIG. 3 table, dynamic address distribution circuitry 171 responds to the programmed configuration setting by multiplexing (173) the least significant bank address bit (B[0]) together with the host-supplied CID[0] bit onto chip-ID path 179, thereby selecting one of four physical dies via operation of decoder 181. Another three of the bank address bits (B[3:1] in this example) are routed to the bank-group address path via multiplexer 175, while the extra row address bit and the most significant bank address bit are routed via multiplexer 177 onto the bank address path. The dynamic address distribution circuitry responds similarly to specification of a single-die/32-bank emulation mode (for which the host the row/column address field is extended by yet another bit to effect the 4:1 bank-count reduction and 4:1 per-bank capacity expansion in that mode), routing the least two significant bits of the banks address (as the host issues no chip-ID value in view of its perception of a single-die component) onto the chip-ID path, routing the three most significant bits of the bank address onto the bank-group address path and routing the most significant two bits of the row address (or column address) onto the bank address path.

FIG. 4 illustrates an exemplary set of emulation-mode configurations within a stack of sixteen dies, each having 32 storage banks (512 storage banks altogether) arranged in groups of four within respective bank groups. As in the 4-die example of FIG. 3, three configurations are depicted, including an emulation-disabled mode (configuration 0), a 2-die/64-bank emulation mode (configuration 1) and a single-die/32-bank emulation mode. Though not specifically shown, the dynamic address distribution circuitry within the EA memory component includes multiplexing circuitry similar to that of FIG. 3 to route incoming address signals onto the chip-ID, bank-group and bank address paths—performing the routing operations shown with respect to each configuration in accordance with the programmed configuration setting. Thus, when emulation is disabled (config=0), the host issues address signals in accordance with the underlying configuration—essentially as shown for the no-emulation mode in FIG. 3, except with two additional chip-ID bits to enable selection from among the 16 intra-package ranks (16 DRAM dies). Similarly, with respect to the two-die and single-die configurations, the host issues fewer (or no) CID bits and instead supplies extra row/column address bits in accordance with the emulation of enlarged storage banks. As in the FIG. 3 embodiment, the routing of specific subsets of address bits (e.g., within the bank address field, or row address or column address) may be different from those shown—for example, routing the most significant bank address bits onto chip-identifier line 179 instead of the least significant bank address bits.

In a number of embodiments, the emulated-architecture memory components shown in FIG. 1 include circuitry to eliminate or hide (render transparent to the host control component) die-stack performance characteristics that would otherwise impact host controller performance despite availability of single-die emulation modes—obviating, for example, host circuitry and/or operating methodology that may otherwise be required to account for propagation-time differences in accesses to different intra-package ranks and/or time delays required to transfer on-die bus-driving control from one die to another in back-to-back data transfers from different memory dies.

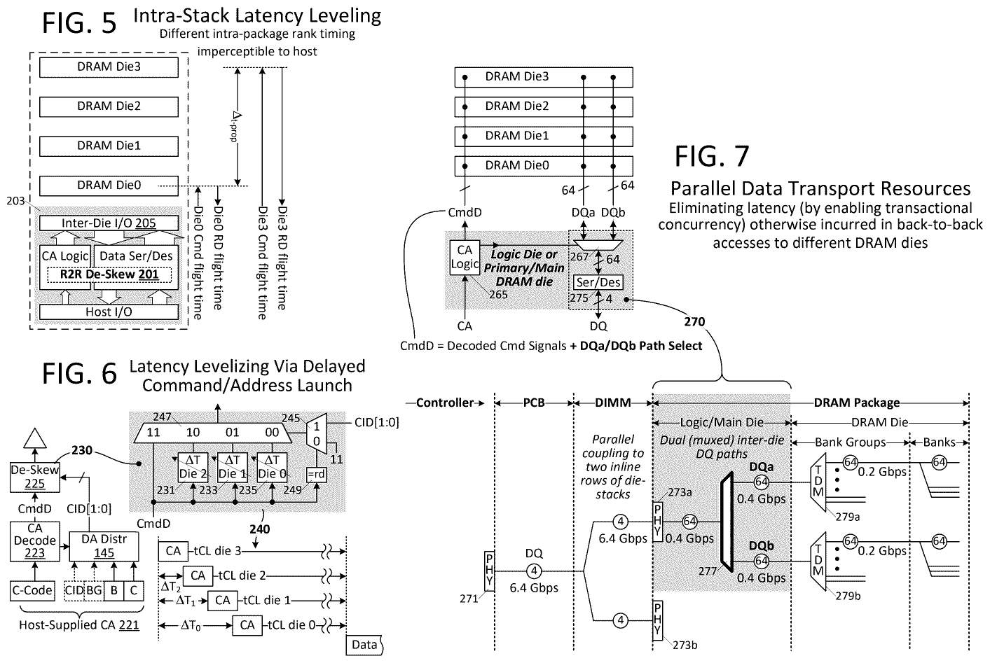

FIG. 5 illustrates an exemplary rank-to-rank deskew circuitry 201 implemented within command/control circuitry 203 (e.g., implemented on the primary memory die or dedicated logic die as shown by corresponding circuitry 131 of FIG. 1) to levelize transactional timing across all physical intra-package ranks despite flight-time differences with respect to outgoing commands and incoming read data. In the four-die stack shown (where the command/control circuitry may be implemented on DRAM die 0 or in a dedicated logic die), command/address propagation time and data propagation time varies according to the physically accessed die as shown in the worst case (i.e., between DRAM dies nearest and furthest from control circuitry 203) by “Δₜ₋ₚᵣₒₚ.” This propagation time difference may (e.g., under worst-case process/temperature/voltage corner and with respect to the two dies closest and furthest from the inter-die I/O circuitry) require the host control component to account for different transactional timing over the distinct address ranges corresponding to different physical storage dies, complicating the otherwise simplified bank/rank state machine made possible by the emulated architecture. Rank-to-rank deskew circuitry 201 avoids this undesired complication (i.e., need to account for different transactional timing over different address ranges) by levelizing the memory read latency across all dies in the stack so that the host component perceives uniform access performance (no difference in access timing/performance) over the entire addressable range of the EA memory component. In a number of embodiments, the rank-to-rank deskew circuitry operates with respect to command/address launch times, staggering those times according to the target DRAM die so that the net transaction latency is uniform from the perspective of the host controller regardless of the physically accessed memory die. In other embodiments, rank-to-rank deskew is implemented within the data path, buffering data from lower-latency dies (or otherwise delaying data propagation—for example, through insertion of a programmable and thus calibratable delay line in the lower-latency data transmission paths) to present a uniform-latency behavior to the host component. In yet other embodiments, rank-to-rank deskew circuitry 201 may be split between the command/address logic and data management circuitry (e.g., serializer/deserializer) with both portions of the split circuit collectively effecting a net incremental latency with respect to the lower-latency memory dies so as to levelize (render uniform) the latency across the complete multi-die memory package.

In one embodiment, shown for example in FIG. 6, memory read latency is levelized by delaying command launch time for the three lower-latency DRAM dies (i.e., the DRAM dies electrically nearest the inter-die I/O circuitry shown at 205 in FIG. 5) to match the memory read latency of the most remote DRAM die (i.e., DRAM die3, the longest-latency DRAM die in this example due to its longer intra-package command/address and data propagation path). More specifically, the command code (“C-Code”) embedded within the host-supplied command/address value 221 is decoded by decoder circuit 223 to yield a decoded command (CmdD) which passes, in turn, through deskew circuit 225 en route to the DRAM dies. The intra-package chip-select signals generated by the dynamic address distribution circuitry (i.e., enabling command/address reception in one of four intra-package dies in this example) is also supplied to the deskew circuitry 225 to select one of three delayed launch times (or a non-delayed launch time) according to the physical memory chip to be accessed. In one embodiment, shown in detail view 230, the deskew circuit includes a set of configurable delay elements 231, 233, 235 (e.g., each having intra-clock cycle delay elements and clock-cycle delay elements to enable fine and coarse timing control, respectively) that are programmed during initial device startup (e.g., as part of a timing calibration operation) to impart levelizing delays—effecting a uniform memory latency across all memory dies as shown in exemplary timing detail 240. In systems where host impact is limited to memory read latency, the deskew circuit may be enabled only in response to memory read commands—that is, multiplexer 245 passes the chip ID value (i.e., CID[1:0] or decoded version thereof) to the control input of delay-select multiplexer 247 (thus selecting one of the delayed propagation paths for any chip ID value other than that corresponding to the most remote, longest latency memory chip) only if the decoded or raw incoming command specifies a read operation (affirmative output from command-compare circuit 249) and otherwise selects the undelayed command/address path. Though not specifically shown, the decoded intra-package chip-select signals may also be subject to delay (i.e., similarly to the selectable delay imposed upon the command/address transmission) and/or chip identifier signal assertion may be extended to account for the variation in command/address propagation through the die stack.

FIG. 7 illustrates an exemplary emulated-architecture memory component through having parallel internal data paths to eliminate bus turnover delay (i.e., latency penalty otherwise incurred when switching data bus driver from one memory die to another and/or from dedicated logic die to memory die). In the depicted embodiment, command/address logic 265 (i.e., within control circuitry as shown at 131 in FIG. 1 and disposed on a dedicated logic die or primary memory die) alternately allocates one of two parallel inter-die data paths, DQa or DQb, for data transport in successive memory access transactions so no data path contention occurs in back-to-back accesses to different DRAM dies (or in any transition from one data bus driver to another). In one embodiment, command/address logic 265 enforces the data path alternation by embedding a path-select bit with the decoded command (“CmdD”) output to the address-specified memory die (informing that memory die whether to receive/output data via DQa or DQb) and toggling that transport path specification as necessary between successive commands. The command/address logic 26 also issues a mux-control signal to transport-path multiplexer 267 at the timing boundary between two internal data I/O operations to switchably connect between the serializer/deserializer circuitry and one of the two parallel data paths—effecting a zero-delay switchover from one data path to the other as signal drivers coupled to the different data paths may be concurrently enabled without contention. Detail view 270 illustrates the data flow between (to or from) the physical signaling interface (PHY 271) of the host control component across the signaling channel (e.g., conductive traces on/within a printed circuit board) to a dual inline memory module (or other memory-module form factor or discrete memory component), where the traces split between PHYs 273a and 273b of respective (different) physical ranks of EA memory components resident on the module (e.g., one such rank on each face of the DIMM). Within the DRAM package, data is subject to 16:1 serialization (outbound read data) and 1:16 deserialization (inbound write data) within serializer/deserializer circuitry (e.g., as shown at 275 in FIG. 7), transitioning between 4-bits per unit interval (UI) at 64 Gbps (64 gigabits per second) to 64 bits per logic die/primary memory die clock cycle, where one UI is 1/16 of that clock cycle). The slower/wider side of the serializer/deserializer circuitry 275 is selectively coupled via multiplexer 277 to one of the two parallel data transport paths DQa and DQb, with those paths coupled, in turn, to bank groups and storage banks within individual dies via multiplexing circuitry 279a/279b. In alternative embodiments, transactional concurrency may be further increased through provision of additional parallel data transport paths and expanded multiplexing circuits. In all cases, the depicted numbers of constituent signaling links within any given segment of the signaling path (i.e., circled number of links) may be greater or smaller than that shown and/or the various depicted signaling rates may be different from those shown.

While presented primarily in the form of stacked DRAM dies (with or without an additional logic/periphery die), the various emulated-architecture memory components discussed above may in all cases be implemented by a non-stacked memory component having one or more individually addressable physical DRAM dies (e.g., disposed side by side) with or without a separate logic/periphery die. For example, a memory component having a single/solitary 64-bank memory die may be programmably configured to emulate a 32-bank memory die with each bank having a doubled (or otherwise increased) number of logically addressable storage rows (with dynamic address distribution circuitry as discussed above used to route an additional row address bit onto physical bank-address/bank-select line within the memory component). In such non-stacked embodiments, intra-component (e.g., intra-package) interconnects may be implemented by wire-bonding, die-to-die cabling, substrate traces (e.g., where two or more dies are disposed adjacent one another on a single layer or multi-layer substrate) and/or any other practicable die-to-die interconnect. In yet other embodiments, emulated-architecture components may have two or more side-by-side die-stacks (e.g., two stacks of memory dies disposed side by side within a package optionally sharing a logic/periphery die or having respective per-stack logic/periphery dies or having fewer logic/periphery dies than the number of memory die stacks). In all such embodiments, the individual memory dies may be constituted by DRAM dies and/or storage dies containing any other practicable types storage arrays (e.g., static random access memory and/or Flash or other non-volatile memory).

The various circuits disclosed herein may be described using computer aided design tools and expressed (or represented), as data and/or instructions embodied in various computer-readable media, in terms of their behavioral, register transfer, logic component, transistor, layout geometries, and/or other characteristics. Formats of files and other objects in which such circuit expressions may be implemented include, but are not limited to, formats supporting behavioral languages such as C, Verilog, and VHDL, formats supporting register level description languages like RTL, and formats supporting geometry description languages such as GDSII, GDSIII, GDSIV, CIF, MEBES and any other suitable formats and languages. Computer-readable media in which such formatted data and/or instructions may be embodied include, but are not limited to, computer storage media in various forms (e.g., optical, magnetic or semiconductor storage media, whether independently distributed in that manner, or stored “in situ” in an operating system).

When received within a computer system via one or more computer-readable media, such data and/or instruction-based expressions of the above described circuits can be processed by a processing entity (e.g., one or more processors) within the computer system in conjunction with execution of one or more other computer programs including, without limitation, net-list generation programs, place and route programs and the like, to generate a representation or image of a physical manifestation of such circuits. Such representation or image can thereafter be used in device fabrication, for example, by enabling generation of one or more masks that are used to form various components of the circuits in a device fabrication process.

In the foregoing description and in the accompanying drawings, specific terminology and drawing symbols have been set forth to provide a thorough understanding of the disclosed embodiments. In some instances, the terminology and symbols may imply specific details that are not required to practice those embodiments. For example, any of the specific numbers of signaling links, bits, data transfer frequencies, serialization/deserialization ratios, memory storage capacities, numbers of dies, address field sizes, numbers of programmably specified emulation configurations, signaling or operating frequencies, component circuits or devices and the like can be different from those described above in alternative embodiments. Additionally, links or other interconnection between integrated circuit devices or internal circuit elements or blocks may be shown as buses or as single signal lines. Each of the buses can alternatively be a single signal line, and each of the single signal lines can alternatively be buses. Signals and signaling links, however shown or described, can be single-ended or differential. Timing edges, however depicted or described, may have rising-edge and/or falling-edge sensitivity in alternative embodiments (or be level sensitive), and active high or low logic levels may be reversed from those shown. A signal driving circuit is said to “output” a signal to a signal receiving circuit when the signal driving circuit asserts (or de-asserts, if explicitly stated or indicated by context) the signal on a signal line coupled between the signal driving and signal receiving circuits. The term “coupled” is used herein to express a direct connection as well as a connection through one or more intervening circuits or structures. Integrated circuit device “programming” can include, for example and without limitation, loading a control value into a register or other storage circuit within the integrated circuit device in response to a host instruction (and thus controlling an operational aspect of the device and/or establishing a device configuration) or through a one-time programming operation (e.g., blowing fuses within a configuration circuit during device production), and/or connecting one or more selected pins or other contact structures of the device to reference voltage lines (also referred to as strapping) to establish a particular device configuration or operation aspect of the device. The terms “exemplary” and “embodiment” are used to express an example, not a preference or requirement. Also, the terms “may” and “can” are used interchangeably to denote optional (permissible) subject matter. The absence of either term should not be construed as meaning that a given feature or technique is required.

Various modifications and changes can be made to the embodiments presented herein without departing from the broader spirit and scope of the disclosure. For example, features or aspects of any of the embodiments can be applied in combination with any other of the embodiments or in place of counterpart features or aspects thereof. Accordingly, the specification and drawings are to be regarded in an illustrative rather than a restrictive sense.

What is claimed is:

1. A memory component comprising:
one or more individually addressable physical memory dies each having a plurality of individually addressable physical memory banks;
a configuration register to store a configuration value that specifies an emulated memory architecture having either (i) fewer individually addressable memory dies than the one or more individually addressable physical memory dies, (ii) fewer individual addressable memory banks than the plurality of individually addressable physical memory banks, or (ii) both fewer addressable memory dies and fewer addressable memory banks than the one or more individually addressable physical memory dies and the plurality of individually addressable physical memory banks, respectively; and
control circuitry to receive a command/address value from an external memory control component and having address distribution circuitry to selectively route, in accordance with the emulated memory architecture specified by the configuration value, constituent address bits of a logical address conveyed in the command/address value onto control signal lines coupled to the one or more individually addressable physical memory dies.

2. The memory component of claim 1 wherein the address distribution circuitry to selectively route the constituent address bits of the logical address onto the control signal lines comprises circuitry to route, in response to at least one emulated memory architecture specified by the configuration value, a row address bit of the logical address onto one of the control signal lines used to select the plurality of individually addressable physical memory banks.

3. The memory component of claim 1 wherein:
the one or more individually addressable physical memory dies comprise a plurality of individually addressable physical memory dies; and
the address distribution circuitry to selectively route the constituent address bits of the logical address onto the control signal lines comprises circuitry to route, in response to at least one emulated memory architecture specified by the configuration value, an address bit of the logical address onto one of the control signal lines used to select between the plurality of individually addressable physical memory dies.

4. The memory component of claim 3 wherein the configuration value specifies an emulated memory architecture having a number of logical memory banks not more than one-fourth the collective number of individually addressable physical memory banks within the plurality of individually addressable physical memory dies and wherein each of the logical memory banks is spanned by an address range at least four times the address range spanned by a single one of the individually addressable physical memory banks.

5. The memory component of claim 1 wherein the one or more individually addressable physical memory dies comprise a plurality of individually addressable physical memory dies, the memory component further comprising latency levelizing circuitry to equalize memory read latency with respect to the plurality of individually addressable physical memory dies such that memory access timing is uniform with respect to the entire address range of the emulated memory architecture.

6. The memory component of claim 1 wherein the one or more individually addressable physical memory dies comprise a plurality of individually addressable physical memory dies, the memory component further comprising parallel data paths each coupled in common to each of the individually addressable physical memory dies such that two of the individually addressable physical memory dies may concurrently drive signals onto respective ones of the parallel data paths.

7. The memory component of claim 1 wherein the one or more individually addressable physical memory dies comprise a plurality of individually addressable physical memory dies stacked on one another.

8. A memory component comprising:
a stack of individually addressable physical memory dies;
a configuration register to store a configuration value that specifies an emulated memory architecture; and
control circuitry to receive a command/address value from an external memory control component and having address distribution circuitry to selectively route, in accordance with the emulated memory architecture specified by the configuration value, constituent address bits of a logical address conveyed in the command/address value onto control signal lines coupled in common to each of the individually addressable physical memory dies in the stack.

9. The memory component of claim 8 wherein the address distribution circuitry to selectively route the constituent address bits of the logical address onto the control signal lines comprises circuitry to route, in response to at least one emulated memory architecture specified by the configuration value, a row address bit of the logical address onto one of the control signal lines used to select between different individually addressable physical memory banks within the stack of individually addressable physical memory dies.

10. The memory component of claim 9 wherein the emulated memory architecture specified by the configuration value specifies an emulated memory architecture having either (i) fewer individually addressable memory dies than present in the stack of individually addressable physical memory dies, (ii) fewer individually addressable memory banks than the number of individually addressable physical memory banks within the stack of individually addressable physical memory dies, or (iii) both fewer individually addressable memory dies than present in the stack of individually addressable physical memory dies and fewer individually addressable memory banks than the number of individually addressable physical memory banks within the stack of individually addressable physical memory dies.

11. A method of operation within a memory component having one or more individually addressable physical memory dies each having a plurality of individually addressable physical memory banks, the method comprising:
storing, within a configuration register, a configuration value that specifies an emulated memory architecture having either (i) fewer individually addressable memory dies than the one or more individually addressable physical memory dies, (ii) fewer individual addressable memory banks than the plurality of individually addressable physical memory banks, or (ii) both fewer addressable memory dies and fewer addressable memory banks than the one or more individually addressable physical memory dies and the plurality of individually addressable physical memory banks, respectively;
receiving, from an external memory control component, a command/address value that includes a logical address; and
selectively routing, in accordance with the emulated memory architecture specified by the configuration value, constituent address bits of the logical address onto control signal lines coupled to the one or more individually addressable physical memory dies.

12. The method of claim 11 wherein selectively routing the constituent address bits of the logical address onto the control signal lines comprises routing, in response to at least one emulated memory architecture specified by the configuration value, a row address bit of the logical address onto one of the control signal lines used to select the plurality of individually addressable physical memory banks.

13. The method of claim 11 wherein:
the one or more individually addressable physical memory dies comprise a plurality of individually addressable physical memory dies; and
selectively routing the constituent address bits of the logical address onto the control signal lines comprises routing, in response to at least one emulated memory architecture specified by the configuration value, an address bit of the logical address onto one of the control signal lines used to select between the plurality of individually addressable physical memory dies.

14. The method of claim 13 wherein the configuration value specifies an emulated memory architecture having a number of logical memory banks not more than one-fourth the collective number of individually addressable physical memory banks within the plurality of individually addressable physical memory dies and wherein each of the logical memory banks is spanned by an address range at least four times the address range spanned by a single one of the individually addressable physical memory banks.

15. The method of claim 11 wherein the one or more individually addressable physical memory dies comprise a plurality of individually addressable physical memory dies, the method further comprising selectively adding delay to equalize memory read latency with respect to the plurality of individually addressable physical memory dies such that memory read latency is uniform with respect to the entire address range of the emulated memory architecture.

16. The method of claim 11 wherein the one or more individually addressable physical memory dies comprise a plurality of individually addressable physical memory dies, the method further comprising alternately selecting one of two parallel data paths to convey data in successive memory access transactions, each of the two parallel data paths being coupled in common to each of the individually addressable physical memory dies such that two of the individually addressable physical memory dies may concurrently drive signals onto respective ones of the parallel data paths in association with the successive memory access transactions.

17. The method of claim 11 wherein the one or more individually addressable physical memory dies comprise a plurality of individually addressable physical memory dies stacked on one another.
